(19) United States
(12) Patent Application Publication
(10) Pub. No.: US 2026/0150285 A1
(43) Pub. Date: May 28, 2026

(54) MANAGING CONTACT STRUCTURES IN SEMICONDUCTOR DEVICES

(71) Applicant: Yangtze Memory Technologies Co., Ltd., Wuhan (CN)

(72) Inventors: Zhong ZHANG, Wuhan (CN); Kun ZHANG, Wuhan (CN); Di WANG, Wuhan (CN); Wenxi ZHOU, Wuhan (CN); Zhiliang XIA, Wuhan (CN); Zongliang HUO, Wuhan (CN)

(21) Appl. No.: 19/024,211

(22) Filed: Jan. 16, 2025

Related U.S. Application Data
(63) Continuation of application No. PCT/CN2024/134180, filed on Nov. 25, 2024.

(51) Int. Cl. H10B 41/41; H10B 41/20; H10B 43/20; H10B 43/40

(52) U.S. Cl. CPC H10B 41/41; H10B 41/20; H10B 43/20; H10B 43/40

(57) ABSTRACT

The present disclosure relates to methods, devices, and systems for managing contact structures in semiconductor devices. An example semiconductor device includes a first stack of dielectric layers and isolating layers alternating with each other along a first direction, a first contact structure extending in the first stack, and a second contact structure extending in the first stack. The first contact structure is coupled to a first connection layer in the first stack, and the second contact structure is coupled to a second connection layer in the first stack. A size of the first contact structure along a second direction perpendicular to the first direction is greater than a size of the second contact structure along the second direction. The second contact structure extends through the second connection layer.

### CROSS-REFERENCE TO RELATED APPLICATIONS

This application is a continuation of International Application No. PCT/CN 2024/134180, filed on Nov. 25, 2024, the disclosure of which is hereby incorporated by reference in its entirety.

### TECHNICAL FIELD

The present disclosure relates to semiconductor devices and fabrication methods thereof.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a memory array of memory cells and peripheral circuits for facilitating operations of the memory array.

### SUMMARY

The present disclosure describes methods, devices, systems, and techniques for managing contact structures in semiconductor devices.

One aspect of the present disclosure features a semiconductor device. The semiconductor device includes a first stack of dielectric layers and isolating layers alternating with each other along a first direction; a first contact structure extending in the first stack; and a second contact structure extending in the first stack. The first contact structure is coupled to a first connection layer in the first stack, and the second contact structure is coupled to a second connection layer in the first stack. A size of the first contact structure along a second direction perpendicular to the first direction is greater than a size of the second contact structure along the second direction. The second contact structure extends through the second connection layer.

In some implementations, the second contact structure extends through the first stack.

In some implementations, the first contact structure extends through the second connection layer and ends at the first connection layer.

In some implementations, a first area defined by the first connection layer overlaps with a second area defined by the second connection layer in a plan view perpendicular to the first direction. The second contact structure is distanced from the first contact structure along the second direction and distanced from the first connection layer along the second direction.

In some implementations, the first connection layer is between two adjacent isolating layers of the first stack, and is in contact with the first contact structure. The second connection layer is between another two adjacent isolating layers of the first stack, and is in contact with the second contact structure. The first contact structure is surrounded by a contact spacer that includes a dielectric material. The second connection layer is isolated from the first contact structure by the contact spacer.

In some implementations, the semiconductor device further includes a second stack of conductive layers and isolating layers alternating with each other along the first direction. The second stack is adjacent to the first stack along the second direction. The first connection layer is coupled to a first conductive layer of the second stack, and the second connection layer is coupled to a second conductive layer of the second stack.

In some implementations, each of the first contact structure and the second contact structure is separated from the second stack by at least part of the isolating layers and the dielectric layers of the first stack.

In some implementations, the semiconductor device includes one or more first contact structures, and one or more second contact structures. Each of the one or more first contact structures is coupled to a corresponding first connection layer that is coupled to a corresponding first conductive layer of the second stack. Each of the one or more second contact structures is coupled to a corresponding second connection layer that is coupled to a corresponding second conductive layer of the second stack.

In some implementations, a quantity of the one or more first contact structures is equal to a quantity of the one or more second contact structures. Each of the one or more first contact structures is associated with a different corresponding one of the one or more second contact structures.

In some implementations, the one or more first contact structures have opposite sides along the second direction. The one or more second contact structures are arranged on a same side of the one or more first contact structures along a third direction perpendicular to the first direction and the second direction, or are alternatingly arranged on the opposite sides of the one or more first contact structures along the third direction.

In some implementations, the semiconductor device includes a liner layer that includes a first portion and a second portion. The liner layer includes a dielectric material. The first portion of the liner layer is between the second conductive layer and an isolating layer of the second stack adjacent to the second conductive layer, and the second portion of the liner layer is between the second connection layer and an isolating layer of the first stack adjacent to the second connection layer.

In some implementations, the semiconductor device includes a liner layer between the second conductive layer and an isolating layer of the second stack adjacent to the second conductive layer. The liner layer includes a dielectric material. The liner layer is in contact with the second connection layer along the second direction.

In some implementations, a portion of the second connection layer is between the isolating layer and the second conductive layer along the first direction.

In some implementations, the first contact structure includes a first portion and a second portion adjacent to the first portion along the first direction. A slope of a side wall of the first portion is greater than a slope of a side wall of the second portion.

In some implementations, a thickness of the side wall of the first portion is greater than a thickness of the side wall of the second portion.

In some implementations, the first contact structure intersects with the second connection layer at a position at which the first portion and the second portion of the first contact structure are in contact.

In some implementations, the second contact structure is isolated from the first connection layer by a dielectric layer of the first stack that is in contact with the first connection layer along the second direction.

In some implementations, the semiconductor device includes two gate line slit structures arranged along the second direction. Each of the two gate line slit structures extends along a third direction perpendicular to the first direction and the second direction. The first contact structure and the second contact structure are arranged between the two gate line slit structures along the second direction.

In some implementations, the first contact structure and the second contact structure are coupled to a control circuit of the semiconductor device.

In some implementations, the dielectric layers of the first stack include a first dielectric material, the isolating layers of the first stack and the isolating layers of the second stack include a second dielectric material, and the conductive layers of the second stack include a conductive material.

Another aspect of the present disclosure features a method of forming a semiconductor device. The method includes forming a first stack of dielectric layers and isolating layers alternating with each other along a first direction; forming a first contact structure extending in the first stack; and forming a second contact structure extending in the first stack. The first contact structure is coupled to a first connection layer in the first stack. The second contact structure is coupled to a second connection layer in the first stack. The second contact structure extends through the second connection layer. A size of the first contact structure along a second direction perpendicular to the first direction is greater than a size of the second contact structure along the second direction.

In some implementations, forming the first contact structure includes etching a first portion of the first stack to a first dielectric layer to form a first hole structure along the first direction; removing the first dielectric layer through the first hole structure and forming a first sacrificial layer in place of the first dielectric layer; extending the first hole structure along the first direction by etching a second portion of the first stack to a second dielectric layer; removing the second dielectric layer and forming a second sacrificial layer in place of the second dielectric layer; and removing the first sacrificial layer and the second sacrificial layer and forming the second connection layer and the first connection layer; and depositing a conductive material through the first hole structure to be in contact with the first connection layer.

In some implementations, forming the first contact structure includes etching a first portion of the first stack to a first dielectric layer to form a first hole structure along the first direction; removing the first dielectric layer through the first hole structure and forming the second connection layer in place of the first dielectric layer; extending the first hole structure along the first direction by etching a second portion of the first stack to a second dielectric layer; removing the second dielectric layer and forming the first connection layer in place of the second dielectric layer; and depositing a conductive material through the first hole structure to be in contact with the first connection layer.

In some implementations, the method further includes forming a contact spacer that surrounds the first contact structure. The second connection layer is isolated from the first contact structure by the contact spacer.

In some implementations, forming the second contact structure includes etching through the first stack to form a second hole structure; and depositing a conductive material in the second hole structure to be in contact with the second connection layer.

Another aspect of the present disclosure features semiconductor system. The semiconductor system includes a memory device and a memory controller coupled to the memory device and configured to control the memory device. The memory device includes a first stack of dielectric layers and isolating layers alternating with each other along a first direction; a first contact structure extending in the first stack; and a second contact structure extending in the first stack. The first contact structure is coupled to a first connection layer in the first stack, and the second contact structure is coupled to a second connection layer in the first stack. A size of the first contact structure along a second direction perpendicular to the first direction is greater than a size of the second contact structure along the second direction. The second contact structure extends through the second connection layer.

The details of one or more implementations of the subject matter of this present disclosure are set forth in the accompanying drawings and the description below. Other features, aspects, and advantages of the subject; matter will become apparent from the description, the drawings, and the claims.

### BRIEF DESCRIPTION OF DRAWINGS

FIGS. 1A-1B illustrate an example semiconductor device.

FIGS. 2A-2F illustrate an example process of manufacturing a semiconductor device.

FIGS. 3A-3C illustrate another example process of manufacturing a semiconductor device.

FIG. 4 illustrates a flow chart of an example process of manufacturing a semiconductor device.

FIG. 5 illustrates a block diagram of an example system.

Like reference numbers and designations in the various drawings indicate like elements. It is also to be understood that the various exemplary implementations shown in the figures are merely illustrative representations and are not necessarily drawn to scale.

### DETAILED DESCRIPTION

Due to a demand for memory devices with a higher density, a memory device (e.g., a 3D NAND flash memory) can be formed to have a large number of layers and a larger number of word lines. Contact structures can be configured to connect conductive layers (e.g., used as word lines) to a control circuit. The design and fabrication of the contact structures can have a substantial effect on the chip size and the manufacturing cost of the memory device.

In some cases, conductive layers are connected to the control circuit using contact structures of the same type (e.g., first contact structures). For example, each first contact structure is coupled to a first connection layer at the bottom of the first contact structure, where the first connection layer is further coupled to a respective conductive layer. However, as the number of conductive layers in the memory device increases, a larger number of the first contact structures may be needed to connect the conductive layers to the control circuit, and the size (e.g., diameter) and depth of the first contact structure may increase. As such, the first contact structures may take up a large area, which may decrease the memory cell density of the memory device.

The present disclosure provides techniques to reduce the area needed for contact structures in the memory device. In some implementations, different types of contact structure can be used to connect conductive layers to the control circuit. For example, some of the conductive layers (e.g., half of the conductive layers) are connected to the control circuit using first contact structures, while some of the conductive layers (e.g., the other half of the conductive layers) are connected to the control circuit using second contact structures. The second contact structures can have a smaller size than the first contact structures, and can be distributed near the first contact structures. Each second contact structure extends through and is coupled to a second connection layer, which is further coupled to a respective conductive layer. The first contact structures can each extend through a second connection layer and remain isolated from the second connection layer.

Techniques of the present disclosure can provide one or more of the following technical advantages and/or benefits. For example, by using both the first contact structures and the second contact structures, a smaller area is needed to arrange the contact structures as compared to the scenario where only first contact structures are used. As such, the memory cell density of the memory device can be increased, and the chip size of the memory device can be reduced. For another example, the described techniques can be implemented with simple process steps. In some implementations, different or more technical advantages may be achieved.

The described techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as memory devices configured to operate in a SLC (single-level cell) mode, an MLC (multi-level cell) mode, a TLC (triple-level cell) mode, a QLC (quad-level cell) mode, or a PLC mode. Additionally or alternatively, the techniques can be applied to various types of devices and systems, such as secure digital (SD) cards, embedded multimedia cards (eMMC), or solid-state drives (SSDs), embedded systems, among others.

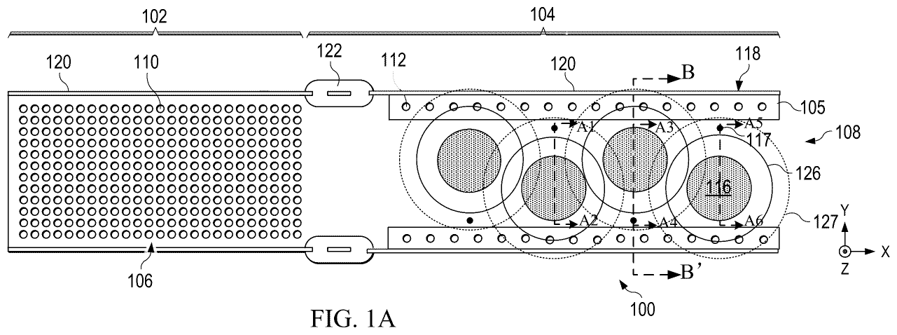

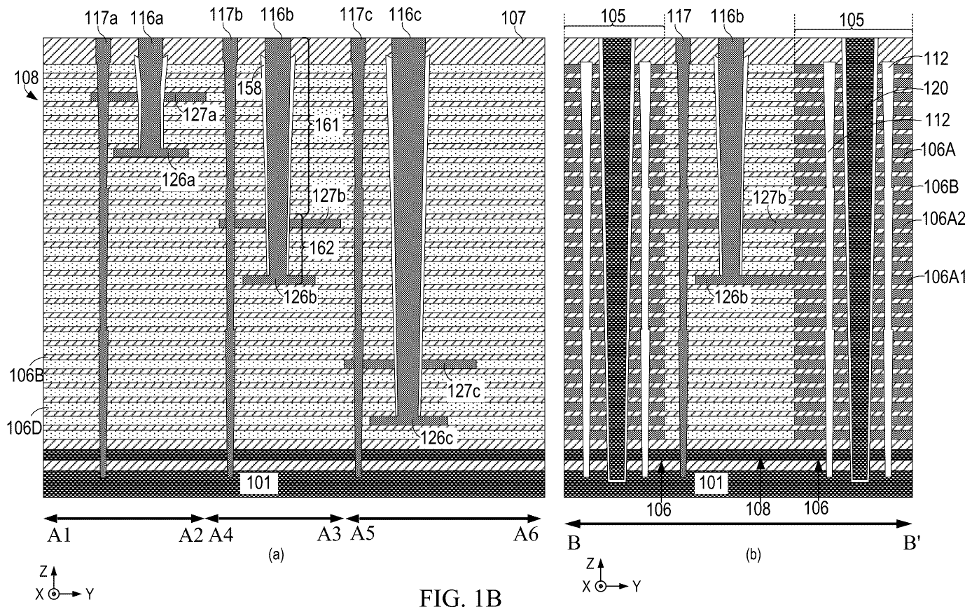

It is noted that X, Y, and Z axes (also referred to as X, Y, and Z directions) are included in FIGS. 1A-3C to further illustrate the spatial relationship of various components in a semiconductor device. A substrate of the semiconductor device can include two lateral surfaces extending laterally in the X-Y plane: a top surface on the front side of the substrate on which a component of the semiconductor device can be formed, and a bottom surface on the backside opposite to the front side of the substrate. Z direction is perpendicular to both the X and Y directions. As used in the present disclosure, whether one component (e.g., a layer or a device) is “on,” “above,” or “below” another component (e.g., a layer or a device) of the semiconductor device is determined relative to the substrate of the semiconductor device in Z direction (the vertical direction perpendicular to the X-Y plane, e.g., the thickness direction of the substrate) when the substrate is positioned in the lowest plane of the semiconductor device in Z direction. The same notion for describing the spatial relationships is applied throughout the present disclosure.

FIG. 1A illustrates a top view of an example semiconductor device 100. In some implementations, the semiconductor device 100 can be a memory device, such as a three-dimensional (3D) NAND memory device. The semiconductor device 100 can include one or more array regions and one or more connection regions configured to provide conductive connections for the one or more array regions. In some implementations, as shown in FIG. 1A, the semiconductor device 100 includes an array region 102 and a connection region 104 adjacent to the array region 102 along a first horizontal direction (e.g., X direction). It is understood that the example in FIG. 1A is for illustration purpose and is not intended to be construed in a limiting sense. In practice, any suitable arrangement of various regions in the semiconductor device 100 can be applied. In some instances, the semiconductor device 100 can have two connection regions 104 and an array region 102 arranged between the two connection regions 104 along X direction. In some other instances, the semiconductor device 100 can have two array regions 102 and a connection region 104 between the two array regions 102 along X direction.

The semiconductor device 100 includes a first stack 106 of alternating conductive layers and isolating layers (e.g., conductive layers 106A and isolating layers 106B as shown in FIG. 1B). In some implementations, a part of the first stack 106 can be in the array region 102, and another part of the first stack 106 can be in the connection region 104. For example, a part of the first stack 106 can be in a tunnel region 105 of the connection region 104. The semiconductor device 100 further includes a second stack 108 of alternating dielectric layers and isolating layers (e.g., dielectric layers 106D and isolating layers 106B as shown in FIG. 1B). In some implementations, the second stack 108 can be in the connection region 104. The first stack 106 is connected to the second stack 108.

The semiconductor device 100 can include an array of channel structures 110 extending through the first stack 106 in the array region 102. Each channel structure 110 can be used to form a string of memory cells coupled in serial along a vertical direction (e.g., Z direction) perpendicular to the first horizontal direction. In some implementations, the semiconductor device 100 can include dummy channel structures 112 (also referred to as dummy memory strings) for process variation control during fabrication and/or for additional mechanical support. For example, the dummy channel structures 112 can extend through the first stack 106 in the tunnel region 105. In some implementations, the dummy channel structures 112 can be in one or more dummy regions or peripheral regions (not shown in FIG. 1A).

The semiconductor device 100 can include one or more gate line slit structures 120. Each gate line slit structure 120 can extend along X direction. The gate line slit structure 120 can extend into both the array region 102 and the connection region 104. Regions around the gate line slit structures 120 in the connection region 104 can be used as the tunnel region 105. In some implementations, the gate line slit structures 120 can divide an array region 102 into multiple memory blocks. For example, a memory block (as shown in FIG. 1A) can be arranged between two memory blocks (not shown in FIG. 1A) along a second horizontal direction (e.g., Y direction) in the array region 102, where the gate line slit structures 120 are boundaries that separate adjacent memory blocks. In some implementations, the gate line slit structure 120 can function as a common source contact for the channel structures 110 in the array region 102.

As shown in FIG. 1A, each gate line slit structure 120 can include multiple segments separated and spaced by separating structures 122. In some implementations, the separating structures 122 can eliminate or reduce stress built in the gate line slit structure 120 during the manufacturing process, thereby preventing the gate line slit structure 120 from bending or cracking. In some implementations, a separating structure 122 can separate a first portion of a gate line slit structure 120 that is in the array region 102 from a second portion of the gate line slit structure 120 that is in the connection region 104, so that different etching processes can be implemented for different portions of the gate line slit structure 120. For example, a first etching process can be implemented to etch away dielectric layers 106D in the array region 102 through the first portion of the gate line slit structure 120. A second etching process can be implemented to etch away dielectric layers 106D in the tunnel region 105 through the second portion of the gate line slit structure 120. Conductive layers 106A can be formed in place of the dielectric layers 106D in the array region 102 and the tunnel region 105.

In some implementations (not shown in FIG. 1A), the gate line slit structure 120 can further include one or more segments extending along the second horizontal direction. For example, the gate line slit structure 120 can include multiple segments connected in an H shape or a T shape. In some implementations, the segments of each gate line slit structure 120 can have similar or a same width (e.g., measured along Y direction). In some other implementations, the segments of each gate line slit structure 120 can have different widths (e.g., measured along Y direction). In some implementations, along Y direction, a width of the segment of the gate line slit structure 120 in the connection region 104 is larger than a width of the segment of the gate line slit structure 120 in the array region 102. For example, the width of the segment in the connection region 104 can be approximately 1.5 to 2 times that of the segment in the array region 102.

The semiconductor device 100 can include contact structures 116, 117 in the connection region 104. The contact structures 116, 117 corresponding to a memory block can be arranged between two gate line slit structures 120 that define the boundary of the corresponding memory block. A contact structure 116 or 117 can be configured to connect a corresponding one of the conductive layers of the first stack 106 to a control circuit of the semiconductor device 100. In some implementations, the semiconductor device 100 can include different types of contact structures, such as first contact structures 116 and second contact structures 117.

The first contact structures 116 and the second contact structures 117 can have different sizes at a surface layer of the second stack 108 (e.g., the surface layer 107 of FIG. 1B). In some implementations, a size of the first contact structure 116 along a horizontal direction (e.g., X direction or Y direction) is greater than a size of the second contact structure 117 along the horizontal direction. For instance, a diameter of the first contact structure 116 is greater than a diameter of the second contact structure 117 at the surface layer of the second stack 108. For example, the diameter of the first contact structure 116 is greater than 300 nm, e.g., 1 μm, 2 μm, 5 μm, or other suitable diameter, and the diameter of the second contact structures 117 ranges from 100-500 nm, e.g., about 150 nm.

The first contact structures 116 and the second contact structures 117 are each coupled to a connection layer in the second stack 108. Each first contact structure 116 can be coupled to a corresponding first connection layer 126 in the second stack 108, and each second contact structure 117 can be coupled to a corresponding second connection layer 127 in the second stack 108. The first connection layers 126 and the second connection layers 127 are each coupled to a conductive layer 106A of the first stack 106, such that the conductive layers 106A of the first stack 106 can be connected to the control circuit through respective connection layers 126, 127 and contact structures 116, 117.

The semiconductor device 100 can include one more first contact structures 116, and one or more second contact structures 117. In some implementations, each first contact structure 116 can be associated with (e.g., paired with) one second contact structure 117, such that the quantity of the first contact structures 116 is equal to the quantity of the second contact structures 117. Each of the one or more first contact structures 116 is associated with a different corresponding one of the one or more second contact structures 117. For example, as shown in FIG. 1A, each first contact structure 116 is associated with a second contact structure 117 near the first contact structure 116.

In a plan view (e.g., in the X-Y plane) perpendicular to the vertical direction, an area (e.g., a circular area) defined by the first connection layer 126 that is coupled to the first contact structure 116 can overlap with an area (e.g., a circular area) defined by the second connection layer 127 that is coupled to the associated second contact structure 117. Further, in the plan view perpendicular to the vertical direction, the second contact structure 117 does not overlap with the area defined by the first connection layer 126 coupled to the associated first contact structure 116. In other words, the second contact structure 117 is distanced from the associated first contact structure 116 along horizontal directions (e.g., X direction and Y direction), and is distanced from the first connection layer 126 coupled to the associated first contact structure 116 along the horizontal directions. Furthermore, in the plan view perpendicular to the vertical direction, the second contact structure 117 does not overlap with the tunnel regions 105, and does not overlap with areas defined by first connection layers 126 or second connection layers 127 coupled to other first or second contact structures (e.g., an adjacent pair of first contact structure 116 and second contact structure 117).

One or more first contact structures 116 can be arranged in a row along the first horizontal direction (e.g., X direction). In some implementations, there is one row of first contact structures 116 between two gate line slit structures 120. In some implementations, there is more than one row of first contact structures 116 between two gate line slit structures 120. Each of the second contact structures 117 can be arranged around the associated first contact structure 116. In some implementations, second contact structures 117 are arranged along the first horizontal direction on the same side of the first contact structures 116. In some implementations, second contact structures 117 are alternatively arranged along the first horizontal direction on opposite sides of the first contact structures 116. For example, as shown in FIG. 1A, two rows of first contact structures 116 are arranged in the connection region 104 between two gate line slit structures 120. Second contact structure 117 associated with the first contact structures 116 in the first row are arranged on a first side of the first contact structures 116, and second contact structures 117 associated with the first contact structures 117 in the second row are arranged on a second side of the first contact structures 117, which is opposite to the first side.

In some implementations, each first contact structure 116 can be associated with (e.g., paired with) more than one second contact structure 117, such that the quantity of second contact structures 117 is greater than the quantity of first contact structures 116. For example, a first contact structure 116 can be paired with two second contact structures 117. In some cases, the two second contact structures 117 are coupled to the same second connection layer 127, such that when one second contact structure 117 fails, connection can be maintained through the other second contact structure 117. In some other case, the two second contact structures 117 are coupled to different second connection layers 127. Each second contact structure 117 is isolated from the second connection layer 127 coupled to the other second contact structure 117.

FIG. 1B illustrates cross-sectional views of the semiconductor device 100 along cut lines A1A2, A3A4, A5A6 and BB′ of FIG. 1A, respectively. The semiconductor device 100 includes a substrate 101, the first stack 106 of alternating conductive layers 106A and isolating layers 106B, and the second stack 108 of alternating dielectric layers 106D and isolating layers 106B. An isolating layer 106B can have a portion between two adjacent conductive layers 106A of the first stack 106 and another portion between two adjacent dielectric layers 106D of the second stack 108.

The first stack 106 and the second stack 108 are provided over the substrate 101. The substrate 101 can be any suitable semiconductor substrate having any suitable semiconductor material, such as monocrystalline, polycrystalline or single crystalline semiconductor. For example, the substrate 101 can include silicon, silicon germanium (SiGe), germanium (Ge), gallium arsenide (GaAs), silicon on insulator (SOI), germanium on insulator (GOI), gallium nitride, silicon carbide, III-V compound, or any combinations thereof. In some implementations, the substrate 101 can be removed from the semiconductor device 100 in a later process of manufacturing the semiconductor device 100 to expose ends of the channel structures 110 (not shown in FIG. 1B) and dummy channel structures 112. Channel structures 110 and dummy channel structures 112 can each include multiple layers including a first isolating layer (e.g., a silicon oxide layer), a dielectric layer (e.g., a silicon nitride layer), a second isolating layer (e.g., a silicon oxide layer), and a channel layer (e.g., a polysilicon layer). The first isolating layer, the dielectric layer and the second isolating layer at the exposed ends of the channel structure 110 and the dummy channel structure 112 can further be removed to expose the channel layer. A semiconductor layer (not shown in FIG. 1B) can be deposited to be in contact with the exposed channel layers of different channel structures 110 (e.g., all channel structures 110 of a memory block) to form a common source.

The semiconductor device 100 can include a surface layer 107 made of a dielectric material (e.g., silicon oxide).

The first stack 106 can include conductive layers 106A and the isolating layers 106B alternating with each other along the vertical direction (e.g., Z direction). The conductive layers 106A can be the same or different from each other in thickness, for example, ranging from 10-500 nm, e.g., about 35 nm. The isolating layers 106B can also be the same or different from each other in thickness, for example, ranging from 10-500 nm, e.g., about 25 nm. It should be noted that the number of the conductive layers 106A and the isolating layers 106B shown in FIG. 1B is for illustration only and that any suitable number of the conductive layers 106A and the isolating layers 106B can be included in the first stack 106. The conductive layers 106A can include any suitable conductive material, such as tungsten (W), cobalt (Co), copper (Cu), aluminum (Al), titanium nitride (TiN), polycrystalline silicon (polysilicon), doped silicon, silicides, or any combination thereof. The isolating layers 106B can include a dielectric material, such as silicon oxide, silicon nitride, silicon oxynitride, or any combination thereof. In some implementations, the isolating layers 106B can also include high-K dielectric materials, such as hafnium oxide, zirconium oxide, aluminum oxide, tantalum oxide, lanthanum oxide, or any combination thereof.

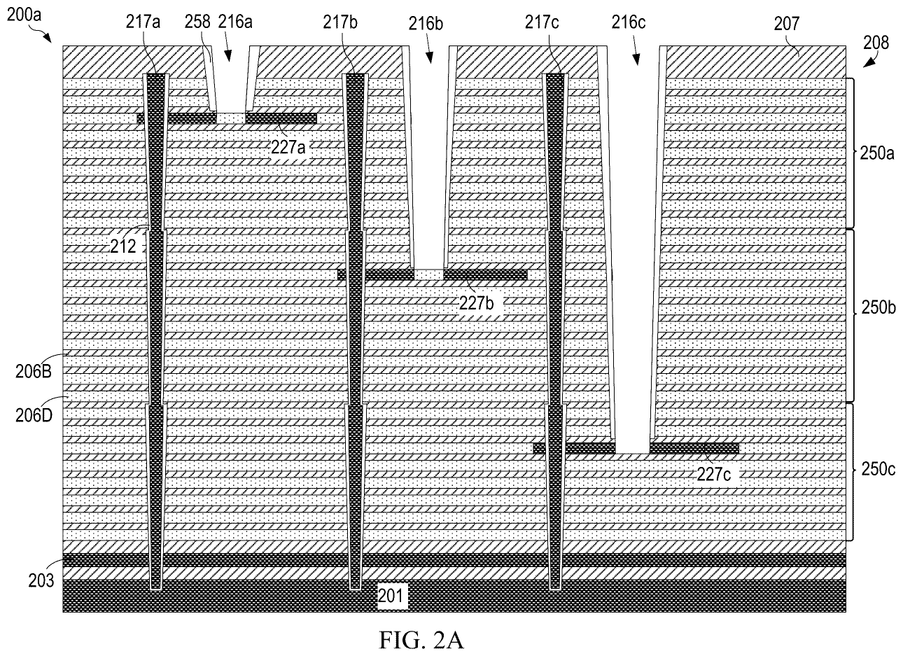

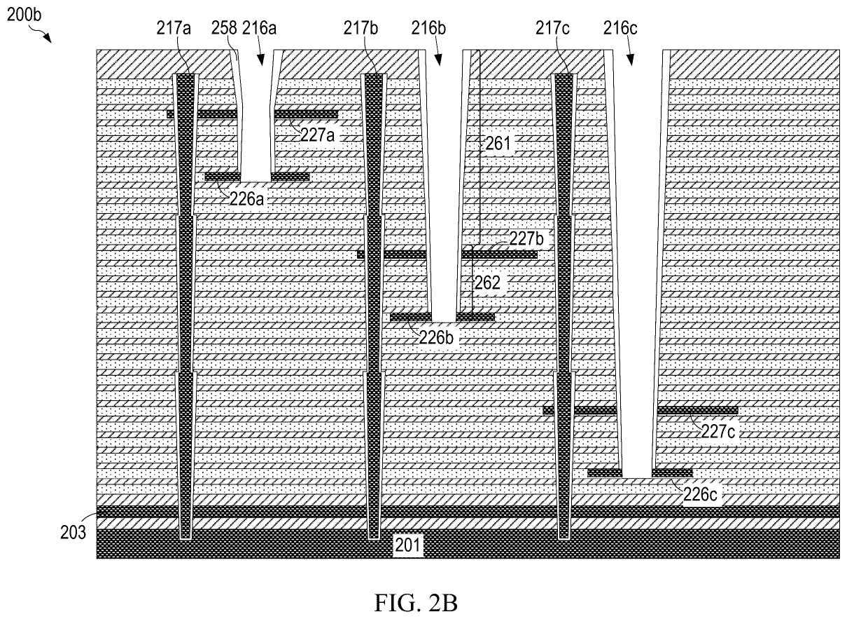

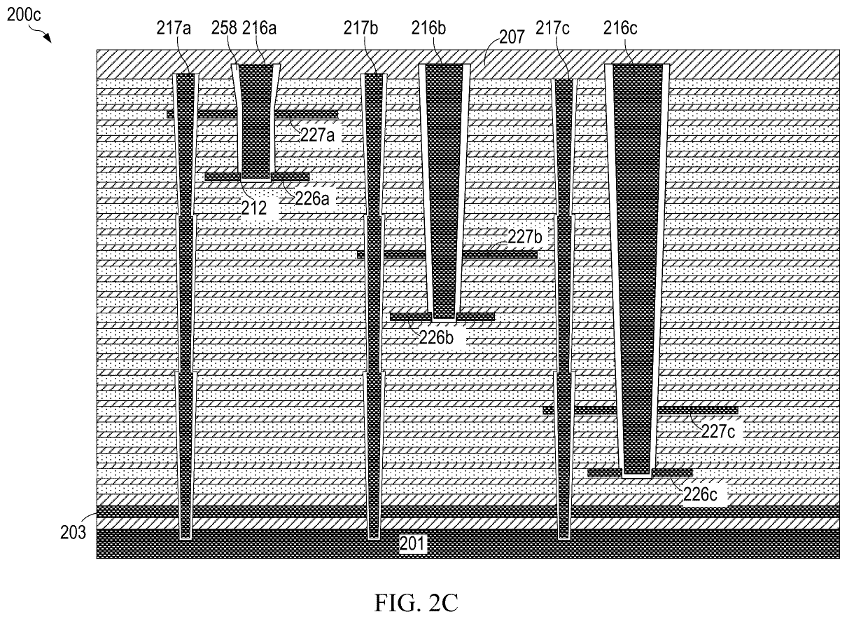

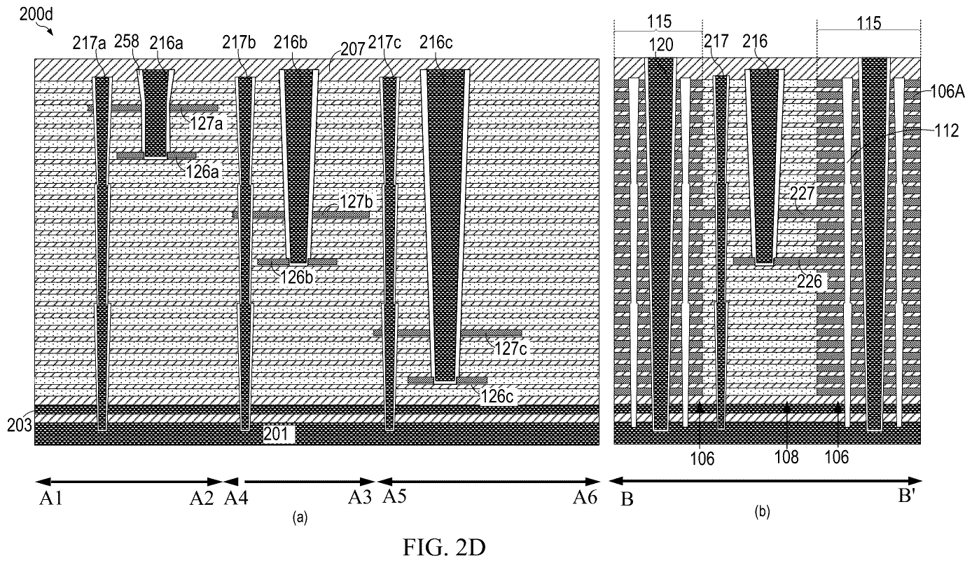

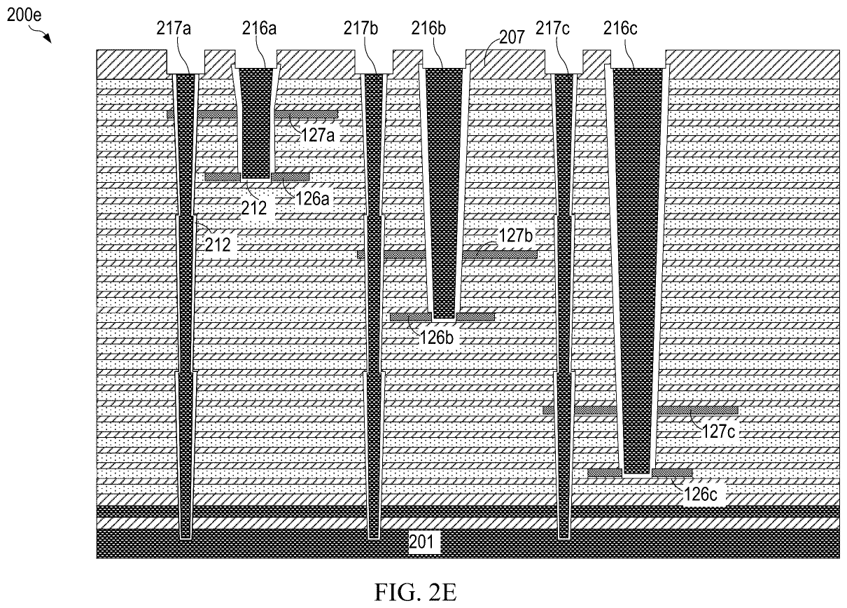

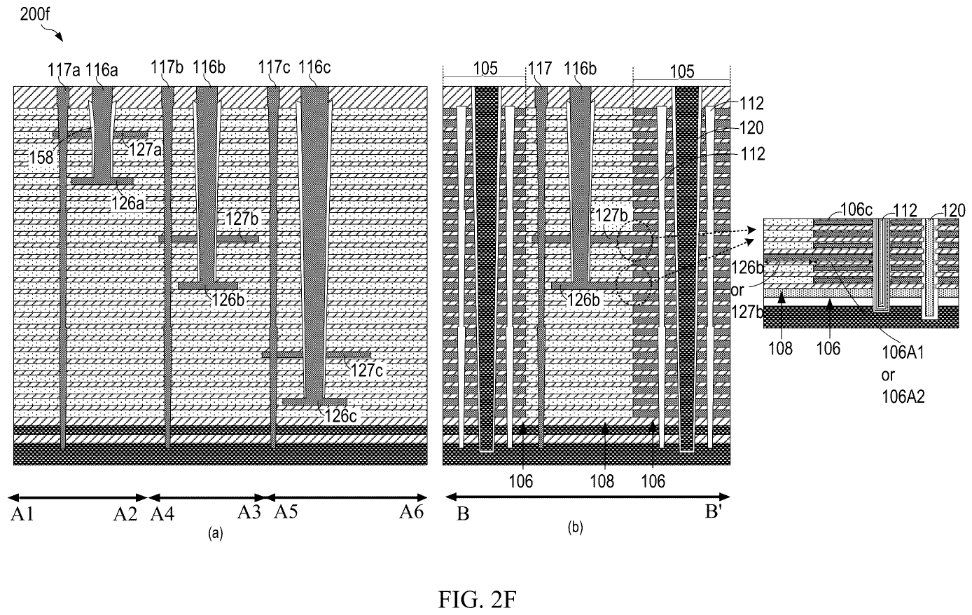

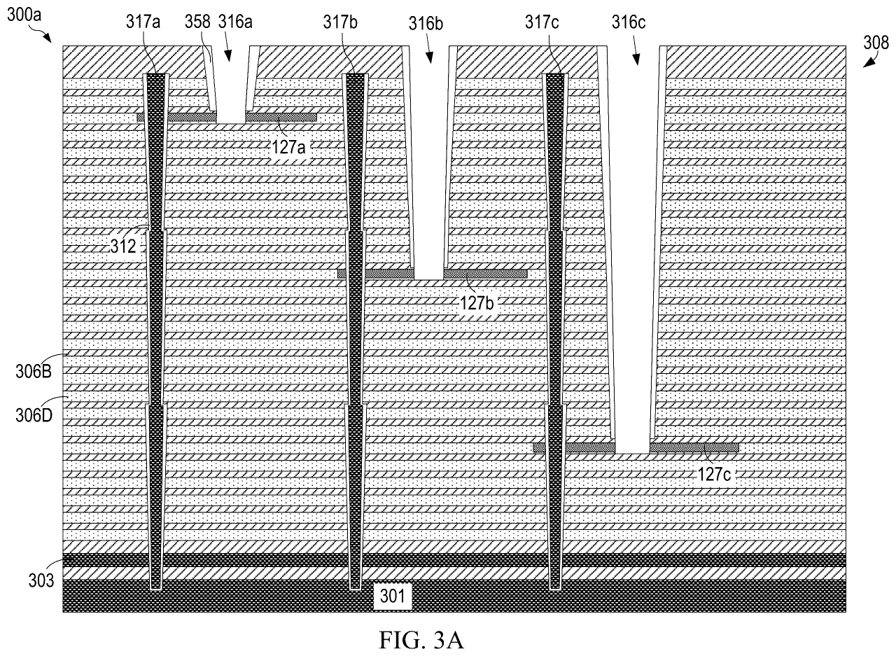

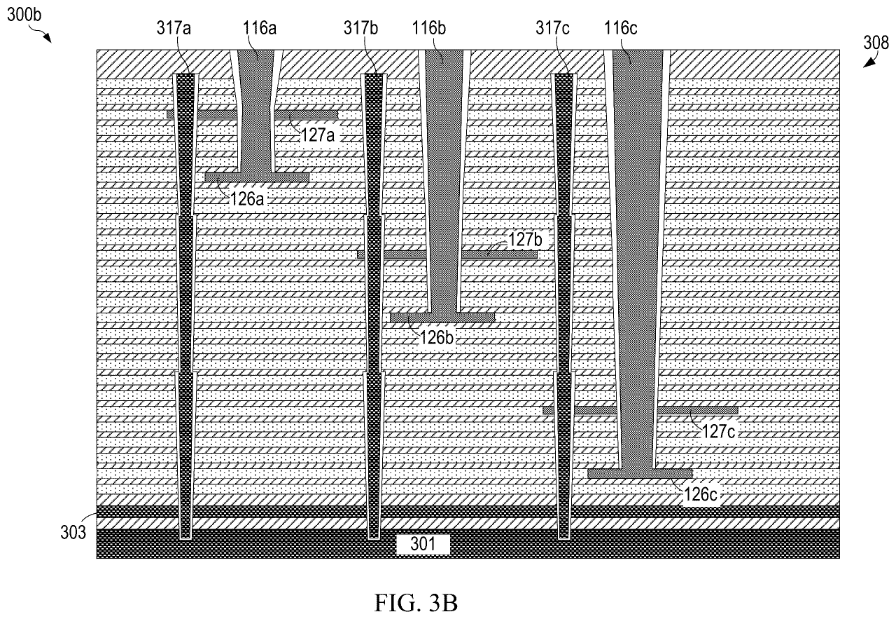

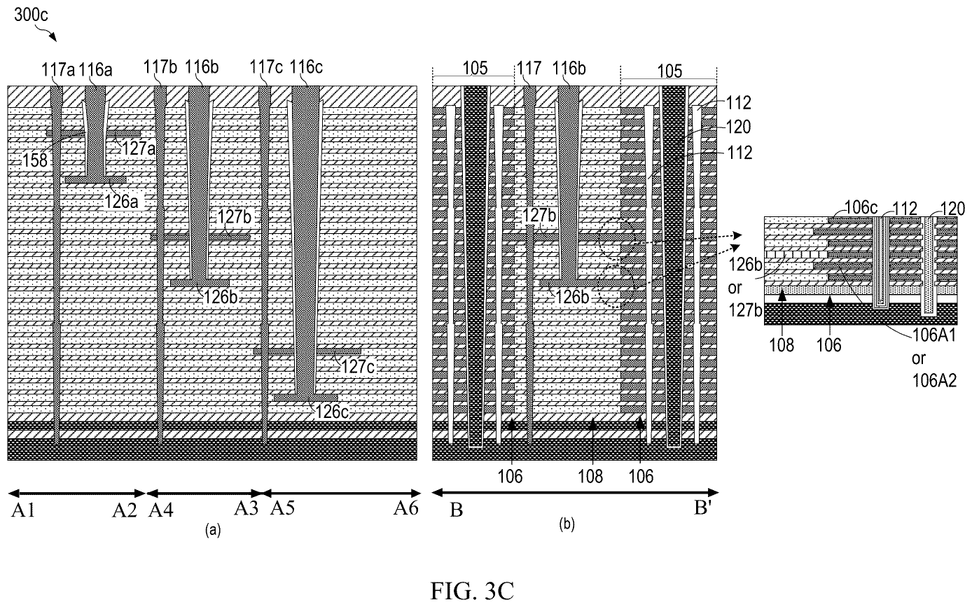

In some implementations, as illustrated in FIG. 2F and FIG. 3C, the first stack 106 includes liner layers 106C. A liner layer 106C can cover part or all of the surface of corresponding conductive layer 106A, and can be formed between the conductive layer 106A and two isolating layers 106B adjacent to the corresponding conductive layer 106A. The liner layer 106C can include a high-K dielectric material (e.g., Al₂O₃). In some examples, the conductive layer 106A includes a metallic material (e.g., W) and an adhesive material (e.g., TiN), and the adhesive material can be deposited between the metallic material and the high-K dielectric material. In some examples, the conductive layer 106A includes the metallic material (e.g., W), and the liner layer 106C includes the adhesive material (e.g., TiN) and the high-K dielectric material (e.g., Al₂O₃).

The second stack 108 include dielectric layers 106D and isolating layers 106B alternating with each other along the vertical direction (e.g., Z direction). The second stack 108 can be connected to the first stack 106. The isolating layers 106B can extend into both the first stack 106 in the tunnel region 105 and the second stack 108 in the connection region 104 along the second horizontal direction (e.g., Y direction). A dielectric layer 106D of the second stack 108 can extend to and be in contact with a corresponding conductive layer 106A (or a liner layer 106C surrounding the corresponding conductive layer 106A) of the first stack 106. To fabricate the first stack 106 and the second stack 108, a series of alternating dielectric layers 106D and isolating layers 106B can be first formed. Then, dielectric layers 106D in a region of the first stack 106 can be etched away, e.g., through an opening formed in the position of the gate line slit structure 120, while dielectric layers 106D in a region of the second stack 108 remain unchanged. Then, the liner layers 106C and the conductive layers 106A can be formed in place of the dielectric layers 106D in the region of the first stack 106 to form the first stack 106.

The isolating layers 106B can include a dielectric material, such as silicon oxide, silicon nitride, silicon oxynitride, or any combination thereof. In some implementations, the dielectric layers 106D can include a dielectric material different from the dielectric material of the isolating layers 106B. For example, the isolating layers 106B can include silicon oxide, and the dielectric layers 106D can include silicon nitride.

The gate line slit structure 120 can extend through the first stack 106 along the vertical direction. In some implementations, as shown in FIG. 1B, the gate line slit structure 120 can extend from the surface layer 107 into the substrate 101 along the vertical direction. The dummy channel structure 112 also can extend through the first stack 106 along the vertical direction. In some implementations, as shown in FIG. 1B, the dummy channel structure 112 can extend into the substrate 101.

The semiconductor device 100 can include first contact structures 116 (including 116a, 116b, 116c) and second contact structures 117 (including 117a, 117b, and 117c). In the following, one first contact structure 116 is paired with one second contact structure 117 as an example for illustration.

Each first contact structure 116 can extend through at least a portion of the second stack 108 (e.g., through a set of dielectric layers 106D and isolating layers 106B of the second stack 108) along the vertical direction. The first contact structure 116 can be surrounded by a contact spacer 158, and the contact spacer 158 can include a dielectric material (e.g., silicon oxide). The first contact structure 116 can include a conductive material (e.g., W, TiN or their combination). In some implementations, the first contact structure 116 can include a body and an outer layer surrounding and in contact with the body, where the body can include a first conductive material (e.g., TiN) or a dielectric material (e.g., silicon oxide), and the outer layer can include a second conductive material (e.g., W).

Each first contact structure 116 is coupled to a first connection layer 126 in the second stack 108. The first connection layer 126 can be between two adjacent isolating layers 106B of the second stack 108. The first connection layer 126 can extend in the X-Y plane (e.g., perpendicular to Z direction) and have a circle shape in the X-Y plane. For example, as shown in FIG. 1B, the first contact structure 116a is coupled to the first connection layer 126a at the bottom of the first contact structure 116a, the first contact structure 116b is coupled to the first connection layer 126b at the bottom of the first contact structure 116b, and the first contact structure 116c is coupled to the first connection layer 126c at the bottom of the first contact structure 116c.

Each second contact structure 117 can extend through the second stack 108 (e.g., all sets of dielectric layers 106D and isolating layers 106B of the second stack 108) along the vertical direction. In some implementations, the second stack 108 includes multiple decks stacked along the vertical direction, and one or more second contact structures 117 extends through only some of the decks. The second contact structure 117 can have the same or similar size as the channel structure 110 or the dummy channel structure 112. The second contact structure 117 can include a conductive material (e.g., W, TiN or their combination).

Each second contact structure 117 is coupled to a second connection layer 127 in the second stack 108. The second connection layer 127 can be between two adjacent isolating layers 106B of the second stack 108. Each second contact structure 117 extends through its corresponding second connection layer 127. The second connection layer 127 can extend in the X-Y plane and have a circle shape in the X-Y plane. In some implementations, the second connection layer 127 has a larger size than the first connection layer 126 in the X-Y plane. For example, as shown in FIG. 1B, the second contact structure 117a extends through the second connection layer 127a, and is coupled to the second connection layer 127a at a position where the second contact structure 117a and the second connection layer 127a intersects; the second contact structure 117b extends through the second connection layer 127b, and is coupled to the second connection layer 127b at a position where the second contact structure 117b and the second connection layer 127b intersects; and the second contact structure 117c extends through the second connection layer 127c, is coupled to the second connection layer 127c at a position where the second contact structure 117c and the second connection layer 127c intersects.

In some implementations, the first contact structure 116 extends through the second connection layer 127 coupled to its paired second contact structure 117, and ends at the first connection layer 126. For example, the first contact structure 116a extends through the second connection layer 127a and ends at the first connection layer 126a, the first contact structure 116b extends through the second connection layer 127b and ends at the first connection layer 126b, and the first contact structure 116c extends through the second connection layer 127c and ends at the first connection layer 126c.

For each pair of first contact structure 116 and second contact structure 117, for example, the first contact structure 116a and the second contact structure 117a, the first contact structure 116a is isolated from the second connection layer 127a (e.g., by the contact spacer 158), and the second contact structure 117a is isolated from the first connection layer 126a (e.g., by a dielectric layer 106D that is in contact with the first connection layer 126a in the X-Y plane).

In some implementations, a first contact structure 116 can include a first portion 161 and a second portion 162 adjacent to the first portion 161 along the vertical direction. For example, the first contact structure 116 intersects with the second connection layer 127 at a position where the first portion 161 and the second portion 162 of the first contact structure 116 are in contact. In some implementations, side walls of the first portion 161 and the second portion 162 can have different slopes. For example, the side wall (e.g., the surrounding contact spacer 158) of the first portion 161 can have a greater slope than the side wall (e.g., the surrounding contact spacer 158) of the second portion 162. In other words, the side wall of the second portion 162 can be steeper than the side wall of the first portion 161. Further, in some implementations, the side wall of the first portion 161 can have a greater thickness (e.g., measured along X or Y direction) than the side wall of the second portion 162.

The first contact structures 116 and the second contact structures 117 can be exposed from the surface layer 107 can be configured to be coupled out to an external circuit (e.g., a control circuit). Each of the first connection layers 126 and the second connection layers 127 are coupled to a respective conductive layer 106A of the first stack 106 in the tunnel region 105. For example, as shown in FIG. 1B, the first connection layer 126b is coupled to the conductive layer 106A1, and the second connection layer 127b is coupled to the conductive layer 106A2. In some implementations, half of the conductive layers 106A in the first stack 106 are connected to the control circuit through first contact structures 116 by being coupled to respective first connection layers 126, and the other half of the conductive layers 106A in the first stack 106 are connected to the control circuit through second contact structures 117 by being coupled to respective second connection layers 127. As one example, the first stack 106 includes a hundred conductive layers 106A numbered in sequence from the surface layer 107 to the substrate 101. Layers 1-10, layers 21-30, layers 41-50, layers 61-70, and layers 81-90 can connect to the control circuit via second contact structures 117. Layers 11-20, layers 31-40, layers 51-60, layers 71-80, and layers 91-100 can connect to the control circuit via first contact structures 116.

In some implementations, the first contact structures 116 and the second contact structures 117 are distanced from the tunnel region 105. Each of the first contact structure 116 and the second contact structure 117 is separated from the first stack 106 in the tunnel region 105 by at least part of the isolating layers 106B and the dielectric layers 106D of the second stack 108.

It should be noted that the number of the first contact structures 116 and the second contact structures 117 in FIG. 1A and FIG. 1B is for illustration only. The semiconductor device 100 can include any suitable number of first contact structures 116 and second contact structures 117.

FIGS. 2A-2F illustrate an example process of fabricating a semiconductor device, such as the semiconductor device 100 as illustrated in FIGS. 1A-1B. FIGS. 2A-2F show cross-sectional views of example semiconductor structures along the cut lines A1A2, A3A4, and A5A6 of FIG. 1A at various stages of the fabrication process. FIGS. 2D and 2F also show cross-sectional views of example semiconductor structures along the cut line BB′ of FIG. 1A at various stages of the fabrication process.

As shown in FIG. 2A, a semiconductor structure 200a is formed. The semiconductor structure 200a includes a substrate 201 and a stack 208 of alternating dielectric layers 206D and isolating layers 206B provided over the substrate 201. The dielectric layers 206D and the isolating layers 206B can alternate in the vertical direction (e.g., Z direction). The isolating layers 206B can include a dielectric material, such as silicon oxide, silicon nitride, silicon oxynitride, or any combination thereof. In some implementations, the dielectric layers 206D can include a dielectric material different from the dielectric material of the isolating layers 206B. For example, the isolating layers 206B can include silicon oxide, and the dielectric layers 206D can include silicon nitride. In some implementations, the semiconductor structure 200a can further include a polysilicon layer 203 between the stack 208 and the substrate 201 along the vertical direction.

As shown in FIG. 2A, channel holes 217 (including 217a, 217b, and 217c) are formed through the stack 208 by an etching process. In some implementations, the stack can include one or more decks (e.g., the upper deck 250a, the middle deck 250b, and the lower deck 250c), where each deck includes a set of alternating dielectric layers 206D and isolating layers 206B. The channel holes 217 can be formed by first forming channel holes through the lower deck 250c, depositing the middle deck 250b on the lower deck 250c, forming channel holes through the middle deck 250b, and then depositing the upper deck 250a on the middle deck 250b, and forming channel holes through the upper deck 250a that are aligned with the channel holes in middle deck 250b and the lower deck 250c. In some cases, some channel holes 217 may extend through only the upper deck 250a, or only through the upper deck 250a and the middle deck 250b.

In some implementations, the channel holes 217 (where the second contact structures 117 of FIGS. 1A-1B will be formed) can be formed during the same process of forming channel holes (not shown in FIG. 2A) in the array region 102 (where channel structures 110 of FIG. 1A will be formed) and channel holes in the tunnel region 105 (where dummy channel structure 112 of FIGS. 1A-1B will be formed). A sacrificial material (e.g., carbon, polysilicon) can be filled in the channel holes 217 and in other channel holes in the array region 102 and the tunnel region 105.

In some implementations, the sacrificial material in the channel holes in the array region 102 and the tunnel region 105 can be removed, so that a first isolating layer (e.g., a silicon oxide layer), a dielectric layer (e.g., a silicon nitride layer), a second isolating layer (e.g., a silicon oxide layer), and a channel layer (e.g., a polysilicon layer) can be filled in the channel holes in sequence to form the channel structures 110 and the dummy channel structures 112.

In some implementations, the sacrificial material (e.g., if it is polysilicon) can be kept in the channel holes 217. In some implementations, the sacrificial material (e.g., if it is carbon) can be removed in the channel holes 217, so that a liner layer 212 (e.g., made of oxide) and another sacrificial material (e.g., polysilicon) can be filled in the channel holes 217, which may offer better mechanical support for later processes. An isolating layer 207 can then be deposited over the stack 208 as a protection layer.

As shown in FIG. 2A, contact holes 216 (including 216a, 216b, and 216c) can each be formed by etching (e.g., through dry etching) a first portion of the stack 208 along the vertical direction to reach a dielectric layer 206D. A contact spacer 258 can be deposited on an inner surface of each contact hole 216. The contact spacer 258 can include a dielectric material, such as silicon oxide. The contact spacer 258 can be deposited using an atomic layer deposition (ALD) method or a chemical vapor deposition (CVD) method. In some implementations, the contact spacer 258 is first deposited on both the inner surface and the bottom surface of the contact holes 216. Then, by an etching process, the contact spacer 258 on the bottom surface of the contact holes 216 is removed to expose the dielectric layers 206D. The dielectric layers 206D exposed by the contact holes 216 can be removed by an etching process, such as wet etching. Taking the contact hole 216a as example, the dielectric layer 206D exposed by the contact hole 216a is etched, such that the etched portion extends into at least one tunnel region 105 and extends further than the channel hole 217a in the X-Y plane. A sacrificial material (e.g., polysilicon) can be filled in place of the etched portion of the dielectric layers 206D to form first sacrificial layers 227 (including 227a, 227b, and 227c). In some implementations, excessive sacrificial material (e.g., deposited on the bottom and on side walls of the contact holes 216) can be removed. The first sacrificial layers 227 each extend into at least one tunnel region 105, and intersect with a respective channel hole 217.

Different contact holes 216a, 216b and 216c can extend to different dielectric layers 206D. For example, the contact hole 216a may extend to the M^{th} dielectric layer of the stack 208, the contact hole 216b may extend to the (M+k)^{th} dielectric layer of the stack 208, and the contact hole 216c may extend to the (M+2k)^{th} dielectric layer of the stack 208, where M and k are positive integers.

As shown in a semiconductor structure 200b of FIG. 2B, the contact holes 216 are each extended along the vertical direction by further etching a second portion of the stack 208 (e.g., one or more pairs of isolating layer 206B and dielectric layer 206D). Each of the contact holes 216 is extended to reach another dielectric layer 206D of the stack 208. For example, the contact hole 216a may extend to the (M+i)^{th} dielectric layer of the stack 208, the contact hole 216b may extend to the (M+k+i)^{th} dielectric layer of the stack 208, and the contact hole 216c may extend to the (M+2k+i)^{th} dielectric layer of the stack 208, where i is a positive integer.

In some implementations, a first portion 261 of a contact hole 216 formed by etching the first portion of the stack 208 can have a different profile from a second portion 262 of the contact hole 216 formed by etching the second portion of the stack 206. For example, the side wall of the first portion 261 can have a greater slope than the side wall of the second portion 262. In some implementations, the first potion 261 of the contact hole 216 can have a different diameter from the second portion 262 of the contact hole. For example, the first portion 261 can have a greater diameter than the second portion 262.

A contact spacer 258 can be deposited again on the bottom and on the side wall of the extended contact holes 216, such that the total thickness of the contact spacer 258 on the side wall of the first portion 261 is greater than the total thickness of the contact spacer 258 on the side wall of the second portion 262. The contact spacer 258 on the bottom of the extended contact holes 216 can be removed to expose the dielectric layers 206D. The exposed dielectric layers 206D can be removed by an etching process, such as wet etching. Taking the contact hole 216a as example, the dielectric layer 206D exposed by the extended contact hole 216a is etched, such that the etched portion extends into at least one tunnel region 105, but does not extend further than the channel hole 217a in the X-Y plane. A sacrificial material (e.g., polysilicon) can be filled in place of the etched portion of the dielectric layers 206D to form second sacrificial layers 226 (including 226a, 226b, and 226c). In some implementations, excessive sacrificial material (e.g., deposited on the bottom and on side walls of the extended contact holes 216) can be removed. The second sacrificial layers 226 each extend into at least one tunnel region 105, but do not intersect any channel holes 217.

As shown in a semiconductor structure 200c of FIG. 2C, liner layers 212 can be deposited on the inner surface of the contact holes 216, and a sacrificial material (e.g., poly silicon) can be deposited in the contact holes 216 on the liner layers 212. In some implementations, the liner layers 212 are made of the same material as the contact spacers 258, such that the liner layers 212 of each contact hole 216 and the contact spacers 258 of the contact hole 216 may form a single isolating structure surrounding the contact hole 216. In some implementations, after removing excess material on the top surface of the semiconductor structure 200c (e.g., by performing a planarization process, such as chemical mechanical polishing (CMP)), an isolating layer 207 can be deposited on the semiconductor structure 200c as a protection layer.

As shown in a semiconductor structure 200d of FIG. 2D, through openings in gate line slit structures 120, dielectric layers 206D in tunnel regions 105, the first sacrificial layers 227, and the second sacrificial layers 226 are removed, so that a conductive material (e.g., a metallic material such as W, TiN, or their combination) can be filled in these places. As such, conductive layers 106A can be formed in place of the dielectric layers 206D in the tunnel regions 105, first connection layers 126 can be formed in place of the second sacrificial layers 226, and second connection layers 127 can be formed in place of the first sacrificial layers 227. In some implementations, a liner layer 106C (e.g., made of high-K dielectric material) can be formed to cover the surface of the conductive material in the conductive layers 106A, the first connection layers 126 and the second connection layers 127.

FIG. 2E illustrates a semiconductor structure 2002, which can be formed by removing portions of the oxide layer 127 to expose the contact holes 216 and the channel holes 217.

FIG. 2F illustrates a semiconductor structure 200f, which can be formed by removing the liner layer 212 and the sacrificial material in the contact holes 216 and the channel holes 217, and depositing a conductive material (e.g., a metallic material such as W, TiN, or their combination) in the contact holes 216 and the channel holes 217 to form the first contact structures 116 and the second contact structures 117, respectively. A liner layer 106C is not formed to cover the surface of the conductive material in the first contact structures 116 and the second contact structures 117. The semiconductor structure 200f can be the semiconductor device 100 of FIGS. 1A-1B.

In some implementations, the liner layer 106C covering the second connection layers 127 at positions where the second connection layers 127 intersect with the channel holes 217 is removed, and the liner layer 106C covering the first connection layer 126 at positions where first connection layers 126 are in contact with the bottom of the contact holes 216 is removed. As such, the first contact structures 116 can be in conductive contact with the first connection layers 126, and the second contact structures 117 can be in conductive contact with the second connection layers 127.

FIG. 2F also includes a magnified view of connections between the first connection layer 126b and the conductive layer 106A1, and between the second connection layer 127b and the conductive layer 106A2. Since the conductive layers 106A, the first connection layers 126b and the second connection layers 127b are formed in the same process, as shown in the magnified view, the liner layer 106C is continuous along the second horizontal direction (e.g., Y direction) from conductive layer 106A to connection layer 126b or 127b. For example, a liner layer 106C includes a first portion and a second portion. The first portion of the liner layer 106C is between the conductive layer 106A1 and an adjacent isolating layer 106B in the first stack 106, and a second portion of the liner layer 106C is between the first connection layer 126b and an adjacent isolating layer 106B in the second stack 108. Similarly, another liner layer 106C includes a first portion and a second portion. The first portion of the liner layer 106C is between the conductive layer 106A2 and an adjacent isolating layer 106B in the first stack 106, and a second portion of the liner layer 106C is between the second connection layer 127b and an adjacent isolating layer 106B in the second stack 108.

FIGS. 3A-3C illustrate another example process of manufacturing a semiconductor device, such as the semiconductor device 100 as illustrated in FIGS. 1A-1B. FIGS. 3A-3C show cross-sectional views of example semiconductor structures along the cut line AA′ of FIG. 1A at various stages of the fabrication process. FIG. 3C also show a cross-sectional view of an example semiconductor structure along the cut line BB′ of FIG. 1A at a stage of the fabrication process.

Different from the process illustrated by FIGS. 2A-2F, where the first connection layers 126 and the second connection layers 127 are formed in the same process as the conductive layers 106A, in the process illustrated by FIGS. 3A-3C, the first connection layers 126 and the second connection layers 127 are formed after the conductive layers 106A are formed.

As shown in FIG. 3A, a semiconductor structure 300a is formed. The semiconductor structure 300a includes a substrate 301 and a stack 308 of alternating dielectric layers 306D and isolating layers 306B provided over the substrate 301. The dielectric layers 306D and the isolating layers 306B can alternate in the vertical direction (e.g., Z direction). The isolating layers 306B can include dielectric material, such as silicon oxide, silicon nitride, silicon oxynitride, or any combination thereof. In some implementations, the dielectric layers 306D can include a dielectric material different from the dielectric material of the isolating layers 306B. For example, the isolating layers 306B can include silicon oxide, and the dielectric layers 306D can include silicon nitride. In some implementations, the semiconductor structure 300a can further include a polysilicon layer 303 between the stack 308 and the substrate 301 along the vertical direction.

Channel holes 317 (including 317a, 317b, and 317c) in the semiconductor structure 300a can be formed in the same or similar ways of forming the channel holes 217 in the semiconductor structure 200a. For example, each channel hole 317 can include a liner layer 312 surrounding a sacrificial material. Contact holes 316 (including 316a, 316b, and 316c) in the semiconductor structure 300a can be formed in the same or similar ways of forming the contact holes 216 in the semiconductor structure 200a. For example, each contact hole 316 can be surrounded by a contact spacer 358.

After forming the contact holes 316 that each exposes a dielectric layer 306D of the stack 308, the dielectric layers 306D exposed by the contact holes 316 can be removed by an etching process, such as wet etching. A conductive material can be deposited in place of the etched portion of the dielectric layers 306D to form second connection layers 127. The second connection layers 127 each extend into at least one tunnel region 105, and intersect with a respective channel hole 317. In some implementations, a liner layer 106C is not formed to cover the surface of the conductive material in the second connection layers 127.

As shown in a semiconductor structure 300b of FIG. 3B, the contact holes 316 are each extended along the vertical direction to reach another dielectric layer 306D of the stack 308. The dielectric layers 306D exposed by the extended contact holes 316 can be removed by an etching process, such as wet etching. A conductive material can be deposited in place of the etched portion of the dielectric layers 306D to form the first connection layers 126. The first connection layers 126 each extend into at least one tunnel region 105, but do not intersect any channel holes 317. In some implementations, a liner layer 106C is not formed to cover the surface of the conductive material in the first connection layers 126.

FIG. 3C illustrates a semiconductor structure 300c, which can be formed by removing the liner layer 312 and the sacrificial material in the channel holes 317, and depositing a conductive material in the channel holes 317 to form the second contact structures 117. A liner layer 106C is not formed to cover the surface of the conductive material in the second contact structures 117. The semiconductor structure 200f can be the semiconductor device 100 of FIGS. 1A-1B.

FIG. 3C also includes a magnified view of connections between the first connection layer 126b and the conductive layer 106A1, and between the second connection layer 127b and the conductive layer 106A2. Since the conductive layers 106A are formed in an earlier process than the first connection layers 126b and the second connection layers 127b, as shown in the magnified view, the liner layer 106C is not continuous along the second horizontal direction (e.g., Y direction) from conductive layer 106A to connection layer 126b or 127b. For example, the liner layer 106C only exists between the conductive layer 106A1 and an adjacent isolating layer 106B in the first stack 106, but does not exist between the first connection layer 126b and an adjacent isolating layer 106B in the second stack 108. Similarly, the liner layer 106C only exists between the conductive layer 106A2 and an adjacent isolating layer 106B in the first stack 106, but does not exist between the second connection layer 127b and an adjacent isolating layer 106B in the second stack 108.

In some implementations, when forming the conductive layers 106A, liner layers 106C are formed to cover the surface of the conductive material in the conductive layers 106A. In such case, the liner layers 106C at positions where the connection layers 126b, 127b are in contact with the conductive layers 106A need to be removed. During the removing process, besides the liner layer 106C between the connection layers 126b, 127b and conductive layers 106A along the second horizontal direction (e.g., Y direction), a portion of the liner layer 106C between the conductive layer 106A and adjacent isolating layers 106B of the first stack 106 may also be removed. As such, when forming the connection layer 126b or 127b, a portion of the connection layer 126b or 127b can extend between the conductive layer 106A and adjacent isolating layers 106B (e.g., in place of the removed liner layers 106C).

Connections between the first connection layer 126a and a conductive layer 106A, between the second connection layer 127a and the conductive layer 106A, between the first connection layer 126c and a conductive layer 106A, and the second connection layer 127c and a conductive layer 106A can be similar as above.

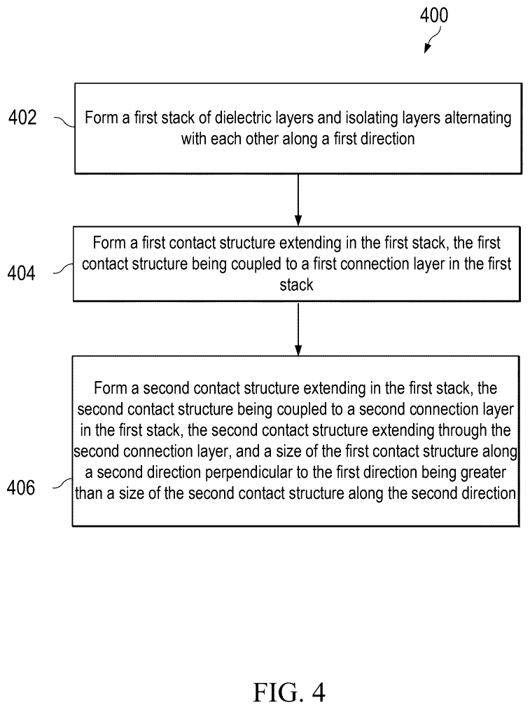

FIG. 4 illustrates a flow chart of an example process 400. The process 400 can be performed to form a semiconductor device (e.g., the semiconductor device 100 illustrated by FIGS. 1A-1B). The process 400 can be described in view of FIGS. 2A-2F and FIGS. 3A-3C. The process 400 can include one or more steps of the fabrication process of forming the semiconductor structures in FIGS. 2A-2F and FIGS. 3A-3C. It is understood that the operations shown in process 400 are not exhaustive and that other operations can be performed as well before, after, or between any of the illustrated operations. Further, some of the operations may be performed simultaneously, or in a different order than shown in FIG. 4.

At 402, a first stack (e.g., the stack 108 of FIGS. 1A-1B) is formed. The first stack include dielectric layers (e.g., dielectric layers 106D of FIGS. 1A-1B) and isolating layers (e.g., isolating layers 106B of FIGS. 1A-1B) alternating with each other along a first direction (e.g., Z direction). The stack can be arranged in a connection region (e.g., the connection region 104 of FIG. 1A) of the semiconductor device.

At 404, a first contact structure (e.g., the first contact structure 116a, 116b or 116c of FIG. 1B) that extends in the first stack is formed. The first contact structure is coupled to a first connection layer (e.g., the first connection layer 126a, 126b, or 126c of FIG. 1B) in the first stack.

In some implementations, forming the first contact structure includes etching a first portion of the first stack to a first dielectric layer (e.g., a dielectric layer 206D of FIG. 2A) to form a first hole structure (e.g., a contact hole 216 of FIG. 2A) along the first direction; removing the first dielectric layer through the first hole structure and forming a first sacrificial layer (e.g., first sacrificial layer 227 of FIG. 2B) in place of the first dielectric layer; extending the first hole structure along the first direction by etching a second portion of the first stack to a second dielectric layer (e.g., another dielectric layer 206D of FIG. 2B); removing the second dielectric layer and forming a second sacrificial layer (e.g., second sacrificial layer 226 of FIG. 2B) in place of the second dielectric layer; removing the first sacrificial layer and the second sacrificial layer and forming the second connection layer and the first connection layer; and depositing a conductive material through the first hole structure to be in contact with the first connection layer.

In some implementations, forming the first contact structure includes etching a first portion of the first stack to a first dielectric layer (e.g., a dielectric layer 306D of FIG. 3A) to form a first hole structure (e.g., a contact hole 316 of FIG. 3A) along the first direction; removing the first dielectric layer through the first hole structure and forming the second connection layer in place of the first dielectric layer; extending the first hole structure along the first direction by etching a second portion of the first stack to a second dielectric layer (e.g., another dielectric layer 306D of FIG. 3B); removing the second dielectric layer and forming the first connection layer in place of the second dielectric layer; and depositing a conductive material through the first hole structure to be in contact with the first connection layer.

In some implementations, a contact spacer (e.g., contact spacer 158 of FIG. 1B) is formed around the first contact structure. The second connection layer is isolated from the first contact structure by the contact spacer.

At 406, a second contact structure (e.g., the second contact structure 117a, 117b, or 117c of FIG. 1B) that extends in the first stack is formed. The second contact structure is coupled to a second connection layer (e.g., the second connection layer 127a, 127b, or 127c of FIG. 1B) in the first stack. The second contact structure extends through the second connection layer. A size of the first contact structure along a second direction (e.g., Y direction) perpendicular to the first direction is greater than a size of the second contact structure along the second direction.

In some implementations, forming the second contact structure includes etching through the first stack to form a second hole structure (e.g., channel hole 217 of FIG. 2A, or channel hole 317 of FIG. 3A); and depositing a conductive material in the second hole structure to be in contact with the second connection layer.

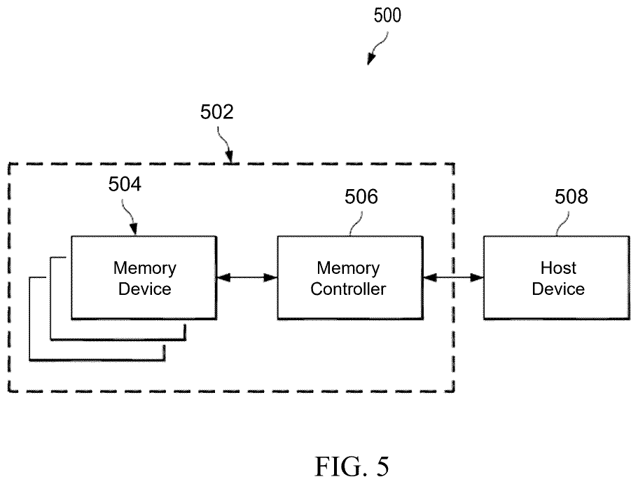

FIG. 5 illustrates a block diagram of an example system 500. The system 500 can have one or more semiconductor devices (e.g., memory devices), according to one or more implementations of the present disclosure. The system 500 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage. As shown in FIG. 5, the system 500 can include a host device 508 and a memory system 502 having one or more memory devices 504 and a memory controller 506. Host device 508 can include a processor of an electronic device, such as a central processing unit (CPU), or a system-on-chip (SoC), such as an application processor (AP). Host device 508 can be configured to send or receive data to or from the one or more memory devices 504.

A memory device 504 can be any memory device disclosed in the present disclosure, such as a semiconductor device (e.g., a NAND Flash memory) as shown in FIGS. 1A-1B. Memory controller 506 (a.k.a., a controller circuit) is coupled to memory device 504 and host device 508. Consistent with implementations of the present disclosure, memory device 504 can include a plurality of conductive interconnections through a cover layer that are in contact with conductive pads in a conductive pad layer, and memory controller 506 can be coupled to memory device 504 through at least one of the plurality of conductive interconnections. Memory controller 506 is configured to control memory device 504. For example, memory controller 506 may be configured to operate a plurality of channel structures via word lines. Memory controller 506 can manage data stored in memory device 504 and communicate with host device 508.

In some implementations, memory controller 506 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 506 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 506 can be configured to control operations of memory device 504, such as read, erase, and program (or write) operations. Memory controller 506 can also be configured to manage various functions with respect to the data stored or to be stored in memory device 504 including, but not limited to bad-block management, garbage collection, logical-to-physical address conversion, wear leveling, etc. In some implementations, memory controller 506 is further configured to process error correction codes (ECCs) with respect to the data read from or written to memory device 504. Any other suitable functions may be performed by memory controller 506 as well, for example, formatting memory device 504.

Memory controller 506 can communicate with an external device (e.g., host device 508) according to a particular communication protocol. For example, memory controller 506 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 506 and one or more memory devices 504 can be integrated into various types of storage devices, for example, be included in the same package, such as a universal Flash storage (UFS) package or an eMMC package. That is, memory system 502 can be implemented and packaged into different types of end electronic products. In one example as shown in FIG. 5, memory controller 506 and a single memory device 504 may be integrated into a memory card. Memory card can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” or “approximately” can indicate a value of a given quantity that varies within, for example, 10-30% of the value (e.g.,. +−. 10%,. +−. 20%, or. +−. 30% of the value). As used herein, the term “substantially” refers to a majority of, or mostly, as in at least about 50%, 60%, 70%, 80%, 90%, 95%, 96%, 97%, 98%, 99%, 99.5%, 99.9%, 99.99%, or at least about 99.999% or more.

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
a first stack of dielectric layers and isolating layers alternating with each other along a first direction;
a first contact structure extending in the first stack, wherein the first contact structure is coupled to a first connection layer in the first stack; and
a second contact structure extending in the first stack, wherein the second contact structure is coupled to a second connection layer in the first stack, wherein a size of the first contact structure along a second direction perpendicular to the first direction is greater than a size of the second contact structure along the second direction, wherein the second contact structure extends through the second connection layer.

2. The semiconductor device of claim 1, wherein the second contact structure extends through the first stack.

3. The semiconductor device of claim 1, wherein the first contact structure extends through the second connection layer and ends at the first connection layer.

4. The semiconductor device of claim 1, wherein a first area defined by the first connection layer overlaps with a second area defined by the second connection layer in a plan view perpendicular to the first direction, and
wherein the second contact structure is distanced from the first contact structure along the second direction and distanced from the first connection layer along the second direction.

5. The semiconductor device of claim 1, wherein the first connection layer is between two adjacent isolating layers of the first stack, and is in contact with the first contact structure,
wherein the second connection layer is between another two adjacent isolating layers of the first stack, and is in contact with the second contact structure, and
wherein the first contact structure is surrounded by a contact spacer that comprises a dielectric material, and wherein the second connection layer is isolated from the first contact structure by the contact spacer.

6. The semiconductor device of claim 1, further comprising a second stack of conductive layers and isolating layers alternating with each other along the first direction, wherein the second stack is adjacent to the first stack along the second direction,
wherein the first connection layer is coupled to a first conductive layer of the second stack, and the second connection layer is coupled to a second conductive layer of the second stack.

7. The semiconductor device of claim 6, wherein each of the first contact structure and the second contact structure is separated from the second stack by at least part of the isolating layers and the dielectric layers of the first stack.

8. The semiconductor device of claim 6, comprising:
one or more first contact structures, each of the one or more first contact structures being coupled to a corresponding first connection layer that is coupled to a corresponding first conductive layer of the second stack; and
one or more second contact structures, each of the one or more second contact structures being coupled to a corresponding second connection layer that is coupled to a corresponding second conductive layer of the second stack.

9. The semiconductor device of claim 8, wherein a quantity of the one or more first contact structures is equal to a quantity of the one or more second contact structures, and each of the one or more first contact structures is associated with a different corresponding one of the one or more second contact structures.

10. The semiconductor device of claim 8, wherein the one or more first contact structures have opposite sides along the second direction, and
wherein the one or more second contact structures are arranged on a same side of the one or more first contact structures along a third direction perpendicular to the first direction and the second direction, or are alternatingly arranged on the opposite sides of the one or more first contact structures along the third direction.

11. The semiconductor device of claim 6, comprising:
a liner layer that comprises a first portion and a second portion, wherein the liner layer comprises a dielectric material,
wherein the first portion of the liner layer is between the second conductive layer and an isolating layer of the second stack adjacent to the second conductive layer, and the second portion of the liner layer is between the second connection layer and an isolating layer of the first stack adjacent to the second connection layer.

12. The semiconductor device of claim 6, comprising:
a liner layer between the second conductive layer and an isolating layer of the second stack adjacent to the second conductive layer, wherein the liner layer comprises a dielectric material, and
wherein the liner layer is in contact with the second connection layer along the second direction.

13. The semiconductor device of claim 1, wherein the first contact structure comprises a first portion and a second portion adjacent to the first portion along the first direction, wherein a slope of a side wall of the first portion is greater than a slope of a side wall of the second portion.

14. The semiconductor device of claim 13, wherein a thickness of the side wall of the first portion is greater than a thickness of the side wall of the second portion.

15. The semiconductor device of claim 1, wherein the second contact structure is isolated from the first connection layer by a dielectric layer of the first stack that is in contact with the first connection layer along the second direction.

16. A method of forming a semiconductor device, the method comprising:
forming a first stack of dielectric layers and isolating layers alternating with each other along a first direction;
forming a first contact structure extending in the first stack, wherein the first contact structure is coupled to a first connection layer in the first stack; and
forming a second contact structure extending in the first stack, wherein the second contact structure is coupled to a second connection layer in the first stack, wherein the second contact structure extends through the second connection layer, and wherein a size of the first contact structure along a second direction perpendicular to the first direction is greater than a size of the second contact structure along the second direction.

17. The method of claim 16, wherein forming the first contact structure comprises:
etching a first portion of the first stack to a first dielectric layer to form a first hole structure along the first direction;
removing the first dielectric layer through the first hole structure and forming a first sacrificial layer in place of the first dielectric layer;
extending the first hole structure along the first direction by etching a second portion of the first stack to a second dielectric layer;
removing the second dielectric layer and forming a second sacrificial layer in place of the second dielectric layer;
removing the first sacrificial layer and the second sacrificial layer and forming the second connection layer and the first connection layer; and
depositing a conductive material through the first hole structure to be in contact with the first connection layer.

18. The method of claim 16, wherein forming the first contact structure comprises:
etching a first portion of the first stack to a first dielectric layer to form a first hole structure along the first direction;
removing the first dielectric layer through the first hole structure and forming the second connection layer in place of the first dielectric layer;
extending the first hole structure along the first direction by etching a second portion of the first stack to a second dielectric layer;
removing the second dielectric layer and forming the first connection layer in place of the second dielectric layer; and
depositing a conductive material through the first hole structure to be in contact with the first connection layer.

19. The method of claim 16, wherein forming the second contact structure comprises:
etching through the first stack to form a second hole structure; and
depositing a conductive material in the second hole structure to be in contact with the second connection layer.

20. A memory system comprising:
a first stack of dielectric layers and isolating layers alternating with each other along a first direction;
a first contact structure extending in the first stack, wherein the first contact structure is coupled to a first connection layer in the first stack; and
a second contact structure extending in the first stack, wherein the second contact structure is coupled to a second connection layer in the first stack, wherein a size of the first contact structure along a second direction perpendicular to the first direction is greater than a size of the second contact structure along the second direction, wherein the second contact structure extends through the second connection layer; and
a memory controller coupled to the memory device and configured to control the memory device.
